(19) United States
(12) Patent Application Publication
(10) Pub. No.: US 2007/0292985 A1
(43) Pub. Date: Dec. 20, 2007

(54) Phase change memory with nanofiber heater

(76) Inventor: Yuegang Zhang, Cupertino, CA (US)

Correspondence Address: TROP PRUNER & HU, PC, 1616 S. VOSS ROAD, SUITE 750, HOUSTON, TX, 77057-2631, US

(21) Appl. No.: 11/454,288

(22) Filed: Jun. 16, 2006

(51) Int. Cl. H01L 21/00

(52) U.S. Cl. 438/95

(57) ABSTRACT

Phase change memories may be formed with nanofiber bottom electrodes or heaters. Because of the use of the relatively well controlled, small diameter nanofibers, better current density, and lower current utilization may be achieved, in some cases, because less phase change material may need to change phase. In some embodiments, the nanofibers may be carbon nanotubes having diameters less than 50 nanometers and heights of greater than 50 nanometers.

### BACKGROUND

This relates generally to phase change memories.

Phase change memory devices use phase change materials, i.e., materials that may be electrically switched between a generally amorphous and a generally crystalline state, for electronic memory application. One type of memory element utilizes a phase change material that may be, in one application, electrically switched between a structural state of generally amorphous and generally crystalline local order or between different detectable states of local order across the entire spectrum between completely amorphous and completely crystalline states. The state of the phase change materials is also non-volatile in that, when set in either a crystalline, semi-crystalline, amorphous, or semi-amorphous state representing a resistance value, that value is retained until changed by another programming event, as that value represents a phase or physical state of the material (e.g., crystalline or amorphous). The state is unaffected by removing electrical power.

### BRIEF DESCRIPTION OF THE DRAWINGS

FIG. 1 is an enlarged, cross-sectional view at an early stage of manufacture in accordance with one embodiment of the present invention;

FIG. 2 is an enlarged, cross-sectional view at a subsequent stage in accordance with one embodiment of the present invention;

FIG. 3 is an enlarged, cross-sectional view at a subsequent stage in accordance with one embodiment of the present invention;

FIG. 4 is an enlarged, cross-sectional view at a subsequent stage in accordance with one embodiment of the present invention;

FIG. 5 is an enlarged, cross-sectional view at a subsequent stage in accordance with one embodiment of the present invention;

FIG. 6 is an enlarged, cross-sectional view at a subsequent stage in accordance with one embodiment of the present invention;

FIG. 7 is an enlarged, cross-sectional view at a subsequent stage in accordance with one embodiment of the present invention;

FIG. 8 is an enlarged, cross-sectional view at a subsequent stage in accordance with one embodiment of the present invention;

FIG. 9 is an enlarged, cross-sectional view of another embodiment at an early stage of manufacture in accordance with one embodiment of the present invention;

FIG. 10 is an enlarged, cross-sectional view at a subsequent stage in accordance with one embodiment of the present invention;

FIG. 11 is an enlarged, cross-sectional view at a subsequent stage in accordance with one embodiment of the present invention; and

FIG. 12 is a system depiction in accordance with one embodiment of the present invention;

### DETAILED DESCRIPTION

In accordance with some embodiments of the present invention, a phase change memory may be formed with a heater using a nanofiber. As used herein, a “nanofiber” may be a conductive or semiconductive elongated element having a much greater length than width. Generally, a nanofiber has a length on the order of nanometers. In some embodiments of the present invention, the nanofiber may have a length greater than 100 nanometers and a width or thickness less than 50 nanometers. In some embodiments, the nanofiber aspect ratio or the ratio of length to width may be 4 or greater. Examples of nanofibers include nanotubes and nanowires.

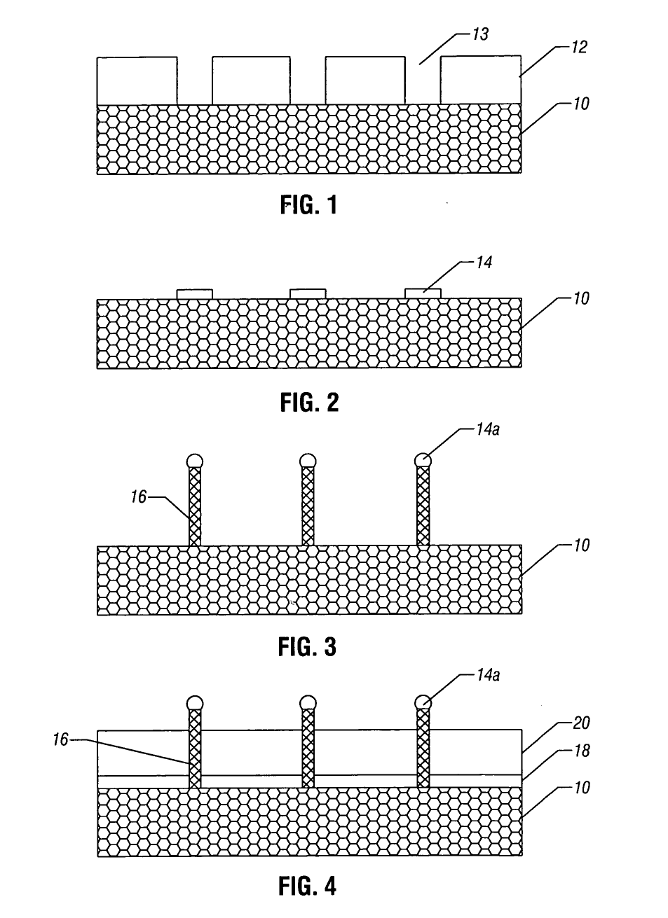

Referring to FIG. 1, a conductive line 10 may be a word line or a bitline, as two examples. It may be formed of a conductive material, such as a metal, or may be formed by doped semiconductor substrate.

Photoresist 12 may be deposited on the line 10. A series of gaps 13 may be defined along the length of the line 10 using photolithography. The gaps 13 may be used to locate catalyst pads 14 shown in FIG. 2. In some embodiments, the catalyst pads 14 may be from 10 to 200 nanometers. They may be formed by deposition directly on the conductive line 10 in one embodiment. They also may be formed over other layers. In addition, they may be formed in connection with vertically extended vias (not shown) connecting to selection devices such as transistors, diodes, or ovonic threshold switches, to mention a few examples.

As shown in FIG. 2, the catalyst pads 14 may then be deposited into the gaps 13 formed in the photoresist 12. The photoresist 12 may be removed, for example, by liftoff. As examples, the catalyst may be formed of an iron or nickel film having a thickness of 1 to 50 nanometers.

Then, referring to FIG. 3, chemical vapor deposition (CVD) or plasma enhanced chemical vapor deposition (PECVD) may be used to grow nanofibers 16. The catalyst pads 14 may change into nanoparticles when heated during nanofiber growth. The catalyst pad 14 thickness may determine the particle size and, hence, the nanofiber 16 diameter. The catalyst pads 14 may be raised to the top of the nanofiber, as indicated at 14a, or remain at the bottom.

Next, a nitride etch stop layer (NESL) 18 and oxide layer 20 may be deposited over the nanofibers 16. In some embodiments, the nanofibers 16 protrude through the oxide layer 20, as indicated in FIG. 4.

In some embodiments, the nanofibers 16 may be single walled carbon nanotubes. In other embodiments, they may be multi-walled carbon nanotubes. In still other embodiments, they may be nanometer dimensioned fibers, for example, formed of carbon or silicon. Generally, the nanofibers 16 may have a diameter or a width of less than 50 nanometers and a vertical dimension or height of greater than 100 nanometers.

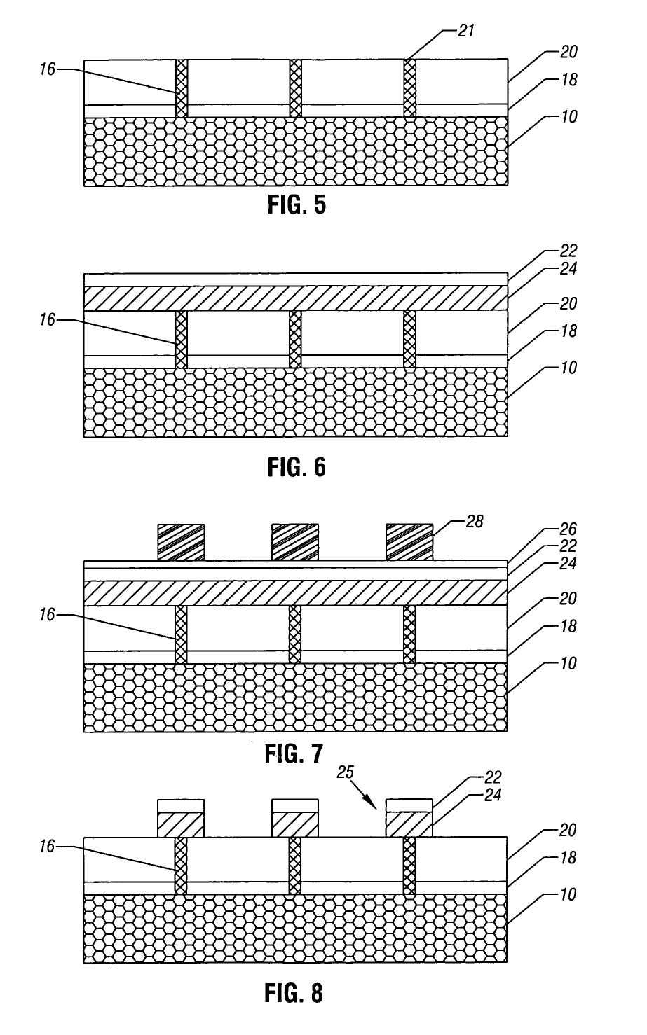

Referring to FIG. 5, the tops of the nanofibers 16 and the catalyst 14a, if any, may then be removed, for example, by chemical mechanical polishing (CMP) to form a uniform height surface 21 that is coplanar with the upper surface of the layer 20.

Thereafter, a chalcogenide 24, a top electrode 22, and a barrier layer (not shown) may then be provided as well, as shown in FIG. 6. The top electrode 22 provides for electrical connection on top of the chalcogenide 24 with the bottom connection provided by the line 10 through the nanofiber 16, which acts, in some embodiments, as a chalcogenide heater or bottom electrode. The chalcogenide 24 may be Ge₂Sb₂Te₅ in one embodiment.

Over the electrode 22 may be deposited a hard mask layer 26 which may be defined into dots 25 aligned over nanofibers 16 to define individual cells as shown in FIG. 7. The photoresist 28 may then be used for etching the dots, as shown in FIG. 8, composed of a distinct geometric area of an upper electrode or top electrode 22 and chalcogenide 24. A variety of shapes may be utilized, but a square shape may be suitable, in some embodiments, for the dots 25. Further processes may include nitride/oxide passivation, metallization to connect the top electrodes 22 to bitlines or to connect the top electrodes 22 to selection devices.

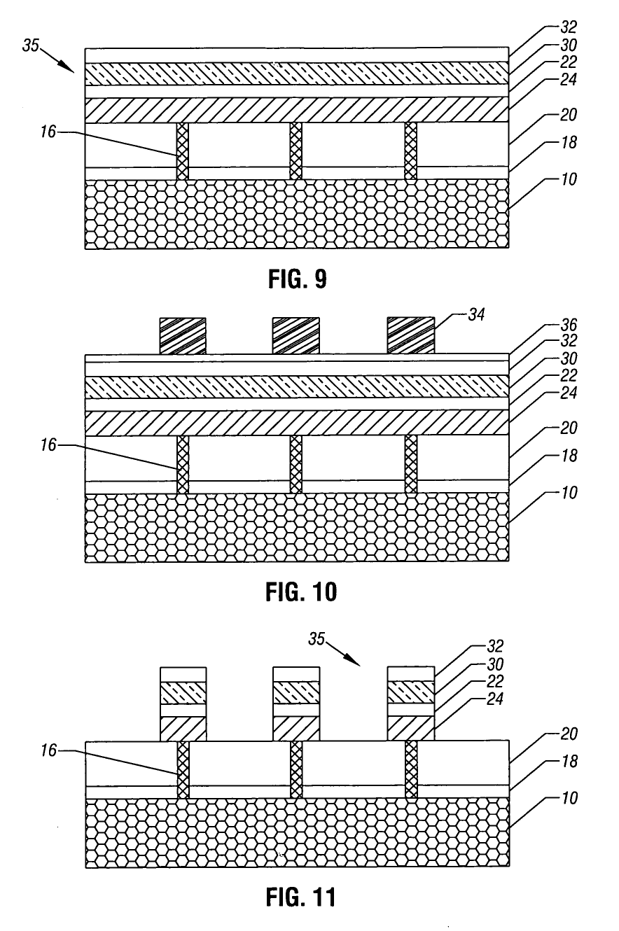

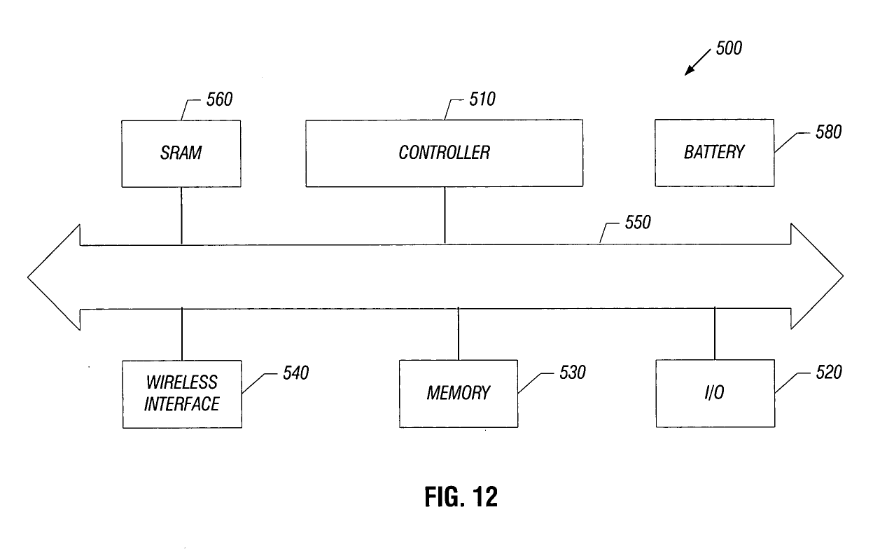

Referring to FIG. 9, in accordance with another embodiment, a select device 35 may be formed as part of each individual cell. In this case, the select device 35 may be formed by an ovonic threshold switch which may use a chalcogenide material that generally does not transition between amorphous and crystalline phases. Instead, it generally stays in the amorphous phase.

Thus, the sequence described in FIGS. 1-5 may be followed. However, in this case, another chalcogenide layer 30 and another electrode 32 may be deposited. The chalcogenide 30 may be a chalcogenide which forms an ovonic threshold switch, together with the electrode 32 and top electrode 22. As an example, the chalcogenide 30 may be Ge₆Si₂₀As₃₂Te₃₆. Thus, the chalcogenide 30 may be one which stays in the amorphous phase. Barrier layers may be provided as needed.

Then, a hard mask 36 may be defined using photoresist 34 as shown in FIG. 10. The hard mask may be used to define the dots 37 as indicated in FIG. 11. In this case, each dot 37 includes an upper electrode layer 32, an ovonic threshold switch chalcogenide layer 30, a top electrode 22, and a chalcogenide material 24. Further processing may include nitride/oxide passivation, metallization to connect the top electrode to bitlines.

In some embodiments, nanofibers may be an advantageous choice for bottom electrodes or heaters because the nanofibers, such as carbon nanotubes, may be very stable electrode material that does not react with the phase change materials in some cases. The diameters of nanofibers may be as small as 1 nanometer or as large as several microns. The diameters may be precisely controlled during the growth process by controlling catalyst particle size with relatively narrow distribution in some embodiments.

The nanofibers may, for example, be grown vertically by catalytic chemical vapor deposition or plasma enhanced chemical vapor deposition at temperatures as low as 400° C. in some embodiments.

In some embodiments, a much smaller diameter heater reduces the amount of material in the phase change layer which must change phase, reducing power and heat loss. In some embodiments, the reduced amount of material that changes phase may result in increased current density.

A select device 35 in the form of the ovonic threshold switch may be used to access a memory element, including the phase change material, during programming or reading of memory element. A select device may be an ovonic threshold switch that can be made of a chalcogenide alloy that does not exhibit an amorphous to crystalline phase change and which undergoes rapid, electric field initiated change in electrical conductivity that persists only so long as a holding voltage is present.

The select device 35 may operate as a switch that is either “off” or “on” depending on the amount of voltage potential applied across the memory cell and, more particularly, whether the current through the select device 35 exceeds its threshold current or voltage, which then triggers the device into the on state. The off state may be a substantially electrically nonconductive state and the on state may be a substantially conductive state, with less resistance than the off state.

In the on state, the voltage across the select device 35 is equal to its holding voltage V_{H} plus IxRon, where Ron is the dynamic resistance from the extrapolated X-axis intercept, V_{H}. For example, a select device 35 may have threshold voltages and, if a voltage potential less than the threshold voltage of a selection device is applied across the selection device, then the select device may remain “off” or in a relatively high resistive state so that little or no electrical current passes through the memory cell and most of the voltage drop from selected row to selected column is across the select device 35. Alternatively, if a voltage potential greater than the threshold voltage of a select device 35 is applied across the select device, then the select device 35 may “turn on,” i.e., operate in a relatively low resistive state so that electrical current passes through the memory cell. In other words, one or more series connected select devices 35 may be in a substantially electrically nonconductive state if less than a predetermined voltage potential, e.g., the threshold voltage, is applied across select devices. Select devices may be in a substantially conductive state if greater than the predetermined voltage potential is applied across select devices. Select devices may also be referred to as an access device, an isolation device, or a switch.

In one embodiment, each select device may comprise a switching material such as, for example, a chalcogenide 30, and may be referred to as an ovonic threshold switch, or simply an ovonic switch. The switching material of select devices 35 may be a material in a substantially amorphous state positioned between two electrodes that may be repeatedly and reversibly switched between a higher resistance “off” state (e.g., greater than about ten megaOhms) and a relatively lower resistance “on” state by application of a predetermined electrical current or voltage potential. In this embodiment, each select device 35 may be a two terminal device that may have a current-voltage (I-V) characteristic similar to a phase change memory element that is in the amorphous state. However, unlike a phase change memory element, the switching material of select devices 35 may not change phase. That is, the switching material of select devices 35 may not be a programmable material, and, as a result, select devices 35 may not be a memory device capable of storing information. For example, the switching material of select devices 35 may remain permanently amorphous and the I-V characteristic may remain the same throughout the operating life.

In the low voltage or low electric field mode, i.e., where the voltage applied across selection device is less than a threshold voltage (labeled V_{TH}), a select device 35 may be “off” or nonconducting, and exhibit a relatively high resistance, e.g., greater than about 10 megaOhms. The selection device may remain in the off state until a sufficient voltage, e.g., V_{TH}, is applied, or a sufficient current is applied, e.g., I_{TH}, that may switch the selection device to a conductive, relatively low resistance on state. After a voltage potential of greater than about V_{TH} is applied across the select device 35, the voltage potential across the select device 35 may drop (“snapback”) to a holding voltage potential, V_{H}. Snapback may refer to the voltage difference between V_{TH} and V_{H} of a select device.

In the on state, the voltage potential across select device 35 may remain close to the holding voltage of V_{H} as current passing through select device 35 is increased. The select device 35 may remain on until the current through the select device drops below a holding current, I_{H}. Below this value, the select device 35 may turn off and return to a relatively high resistance, nonconductive off state until the V_{TH} and I_{TH} are exceeded again.

A single select device may have a V_{H} about equal to its threshold voltage, V_{TH}, (a voltage difference less than the threshold voltage of the memory element) to avoid triggering a reset bit when the select device 35 triggers from a threshold voltage to a lower holding voltage called the snapback voltage.

Programming of the chalcogenide 24 to alter the state or phase of the material may be accomplished by applying voltage potentials to the nanofiber 16 and upper electrode 22, thereby generating a voltage potential across the select device and memory element. When the voltage potential is greater than the threshold voltages of select device 35 and memory element, then an electrical current may flow through the chalcogenide 24 in response to the applied voltage potentials, and may result in heating of the chalcogenide 24.

This heating may alter the memory state or phase of the chalcogenide 24. Altering the phase or state of the chalcogenide 24 may alter the electrical characteristic of memory material, e.g., the resistance of the material may be altered by altering the phase of the memory material. Memory material may also be referred to as a programmable resistive material.

In the “reset” state, memory material may be in an amorphous or semi-amorphous state and in the “set” state, memory material may be in an a crystalline or semi-crystalline state. The resistance of memory material in the amorphous or semi-amorphous state may be greater than the resistance of memory material in the crystalline or semi-crystalline state. It is to be appreciated that the association of reset and set with amorphous and crystalline states, respectively, is a convention and that at least an opposite convention may be adopted.

Using electrical current, memory material may be heated to a relatively higher temperature to amorphosize memory material and “reset” memory material (e.g., program memory material to a logic “0” value). Heating the volume of memory material to a relatively lower crystallization temperature may crystallize memory material and “set” memory material (e.g., program memory material to a logic “1” value). Various resistances of memory material may be achieved to store information by varying the amount of current flow and duration through the volume of memory material.

Turning to FIG. 11, a portion of a system 500 in accordance with an embodiment of the present invention is described. System 500 may be used in wireless devices such as, for example, a personal digital assistant (PDA), a laptop or portable computer with wireless capability, a web tablet, a wireless telephone, a pager, an instant messaging device, a digital music player, a digital camera, or other devices that may be adapted to transmit and/or receive information wirelessly. System 500 may be used in any of the following systems: a wireless local area network (WLAN) system, a wireless personal area network (WPAN) system, a cellular network, although the scope of the present invention is not limited in this respect.

System 500 may include a controller 510, an input/output (I/O) device 520 (e.g. a keypad, display), static random access memory (SRAM) 560, a memory 530, and a wireless interface 540 coupled to each other via a bus 550. A battery 580 may be used in some embodiments. It should be noted that the scope of the present invention is not limited to embodiments having any or all of these components.

Controller 510 may comprise, for example, one or more microprocessors, digital signal processors, microcontrollers, or the like. Memory 530 may be used to store messages transmitted to or by system 500. Memory 530 may also optionally be used to store instructions that are executed by controller 510 during the operation of system 500, and may be used to store user data. Memory 530 may be provided by one or more different types of memory. For example, memory 530 may comprise any type of random access memory, a volatile memory, a non-volatile memory such as a flash memory and/or a memory such as memory discussed herein.

I/O device 520 may be used by a user to generate a message. System 500 may use wireless interface 540 to transmit and receive messages to and from a wireless communication network with a radio frequency (RF) signal. Examples of wireless interface 540 may include an antenna or a wireless transceiver, although the scope of the present invention is not limited in this respect.

References throughout this specification to “one embodiment” or “an embodiment” mean that a particular feature, structure, or characteristic described in connection with the embodiment is included in at least one implementation encompassed within the present invention. Thus, appearances of the phrase “one embodiment” or “in an embodiment” are not necessarily referring to the same embodiment. Furthermore, the particular features, structures, or characteristics may be instituted in other suitable forms other than the particular embodiment illustrated and all such forms may be encompassed within the claims of the present application.

While the present invention has been described with respect to a limited number of embodiments, those skilled in the art will appreciate numerous modifications and variations therefrom. It is intended that the appended claims cover all such modifications and variations as fall within the true spirit and scope of this present invention.

What is claimed is:

1. A method comprising:
forming a phase change memory with a heater formed of a nanofiber.

2. The method of claim 1 including forming the heater of a carbon nanotube.

3. The method of claim 1 including forming the heater of a multi-walled carbon nanotube.

4. The method of claim 1 including forming the heater of a single vertically upstanding carbon nanotube.

5. The method of claim 1 including coupling said nanofiber between a chalcogenide layer and a conductive line.

6. The method of claim 1 including forming said nanofiber with a width of less than 50 nanometers.

7. The method of claim 6 including forming said nanofiber with an aspect ratio of at least 4.

8. The method of claim 1 including defining a discrete chalcogenide dot over said nanofiber.

9. The method of claim 8 including forming said dot with a conductive material and coupling said conductive material to a conductive line.

10. The method of claim 1 including growing a vertically disposed nanofiber between a chalcogenide layer and a conductive line.

11. A phase change memory comprising:
a chalcogenide material; and
a nanofiber electrically coupled to said chalcogenide material.

12. The memory of claim 11 wherein said nanofiber is a carbon nanotube.

13. The memory of claim 11 wherein said nanofiber acts as a heater.

14. The memory of claim 11 wherein said nanofiber is a multi-walled carbon nanotube.

15. The memory of claim 11 wherein said nanofiber extends generally transversely to said chalcogenide material.

16. The memory of claim 11, wherein said nanofiber has an aspect ratio of at least 4.

17. The memory of claim 11 including an ovonic threshold switch electrically coupled to said chalcogenide material.

18. The memory of claim 17 including a dot formed of a region of said chalcogenide material and a conductor aligned with said nanofiber.

19. The memory of claim 11 including a plurality of cells, each cell including an upstanding carbon nanotube, the carbon nanotubes of adjacent cells being generally parallel to one another.

20. The memory of claim 11 including a pair of metal conductors sandwiching said chalcogenide material and said nanofiber.

21. A system comprising:
a processor;
a battery coupled to said processor; and
a phase change memory coupled to said processor, said phase change memory including a carbon nanofiber.

22. The system of claim 21 wherein said carbon nanofiber is positioned proximate to a chalcogenide layer.

23. The system of claim 22 wherein said nanofiber to heat said chalcogenide layer when current is passed through said nanofiber and said chalcogenide layer.

24. The system of claim 21 including a nanofiber is a carbon nanotube.

25. The system of claim 24 wherein said carbon nanotube is a multi-walled carbon nanotube.
